(19) United States
(12) Patent Application Publication
(10) Pub. No.: US 2024/0230739 A1
(43) Pub. Date: Jul. 11, 2024

(54) MEASUREMENT DEVICE FOR ANTENNA AND MEASURING RADIATION PATTERN USING THE SAME

(71) Applicants: Advanced Semiconductor Engineering, Inc., Kaohsiung (TW); National Chung Cheng University, Minhsiung (TW)

(72) Inventors: Sheng-Chi HSIEH, Kaohsiung (TW); Chen-Chao WANG, Kaohsiung (TW); Sheng-Fuh CHANG, Minshiung (TW); Chia-Chan CHANG, Minhsiung (TW); Shih-Cheng LIN, Minhsiung (TW); Yuan-Chun LIN, Minhsiung (TW); Wei-Lun HSU, Minhsiung (TW); Kuo-Hung CHENG, Minhsiung (TW)

(73) Assignees: Advanced Semiconductor Engineering, Inc., Kaohsiung (TW); National Chung Cheng University, Minhsiung (TW)

(21) Appl. No.: 18/094,325

(22) Filed: Jan. 6, 2023

(51) Int. Cl. G01R 29/10; G01R 29/08

(52) U.S. Cl. CPC G01R 29/10; G01R 29/0878

(57) ABSTRACT

A measurement device and a method of measuring a radiation pattern by using the same are provided. The measurement device includes at least one positioner configured to move a first antenna for measuring a main lobe and a back lobe of an electromagnetic wave radiated from the first antenna.

### BACKGROUND

### 1. Field of the Disclosure

The present disclosure relates to a measurement device for an antenna, and in particular to a measurement device including two or more positioners configured to move the antenna under test (AUT).

### 2. Description of Related Art

An antenna radiation pattern measurement device may include a reflector configured to convert an electromagnetic wave to a plane wave and a rotator plate configured to move an AUT, thus reducing dimensions of the measurement device. Radio frequency (RF) radiation emitted by an AUT may not be measured accurately at one or more specific angles, referred to a blind angle, because of the obstruction of a rotator plate.

### SUMMARY

According to some arrangements of the present disclosure, a measurement device includes at least one positioner configured to move a first antenna for measuring a main lobe and a back lobe of an electromagnetic wave radiated from the first antenna.

According to some arrangements of the present disclosure, a measurement device includes a first positioner and a second positioner. The first positioner is configured to move the AUT around a first rotation axis along a first axis. The second positioner is configured to hold the AUT and is configured to adjust an angle between a normal direction of a first surface of the AUT and the first axis.

According to some arrangements of the present disclosure, a method of measuring a radiation pattern of a first antenna includes providing a second antenna. The second antenna is configured to detect an electromagnetic wave radiated from the first antenna. The method also includes moving an orientation of the first antenna to detect a back lobe of the electromagnetic wave radiated from the first antenna via the second antenna. The method further includes calculating a radiation pattern based on the electromagnetic wave detected by the second antenna.

### BRIEF DESCRIPTION OF THE DRAWINGS

Aspects of the present disclosure are readily understood from the following detailed description when read with the accompanying figures. It should be noted that various features may not be drawn to scale for the sake of clarity.

FIG. 1A, FIG. 1B, FIG. 1C, and FIG. 1D are perspective views of a measurement device in accordance with some arrangements of the present disclosure.

FIG. 1E is a schematic view of RF radiation radiated from the AUT.

FIG. 2 shows a system for calculating a radiation pattern of the AUT in accordance with some arrangements of the present disclosure.

FIG. 3A and FIG. 3B are perspective views of a measurement device in accordance with some arrangements of the present disclosure.

FIG. 4A, FIG. 4B, and FIG. 4C are perspective views of a measurement device.

FIG. 5A is a schematic view of a radiation pattern measured by a measurement device.

FIG. 5B is a schematic view of a radiation pattern measured by a measurement device in accordance with some arrangements of the present disclosure.

Common reference numerals are used throughout the drawings and the detailed description to indicate the same or similar components. The present disclosure will be more apparent from the following detailed description taken in conjunction with the accompanying drawings.

### DETAILED DESCRIPTION

The following disclosure provides many different arrangements, or examples, for implementing different features of the provided subject matter. Specific examples of components and arrangements are described as follows. These are, of course, merely examples and are not intended to be limiting. In the present disclosure, reference to the formation or disposal of a first feature over or on a second feature in the description that follows may include arrangements in which the first and second features are formed or disposed in direct contact, and may also include arrangements in which one or more additional features may be formed or disposed between the first and second features, such that the first and second features may not be in direct contact. In addition, the present disclosure may repeat reference numerals and/or letters in the various examples. The same reference numerals and/or letters refer to the same or similar parts. This repetition is for the purpose of simplicity and clarity and does not in itself dictate a relationship between the various arrangements and/or configurations.

Arrangements of the present disclosure are discussed in detail as follows. It should be appreciated, however, that the present disclosure provides many applicable concepts that can be embodied in a wide variety of specific contexts. The specific arrangements discussed are merely illustrative and do not limit the scope of the disclosure.

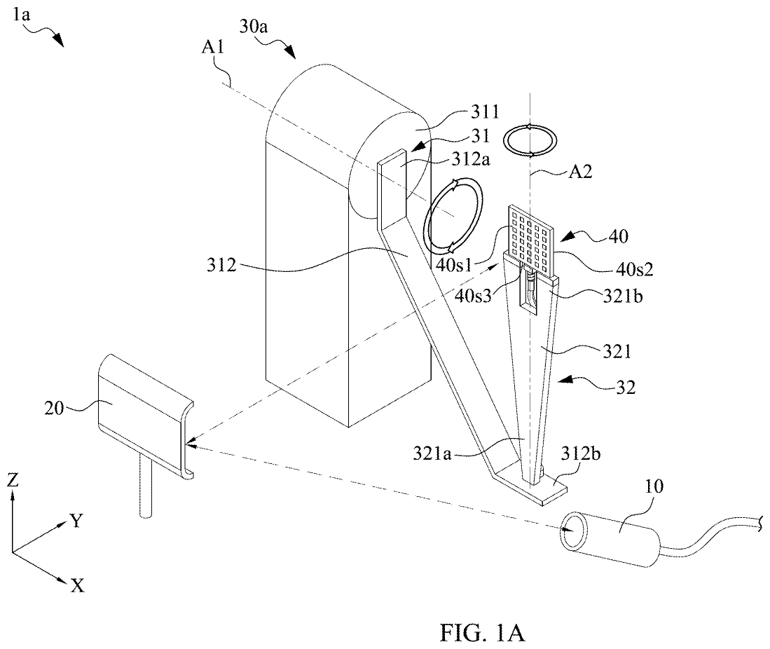

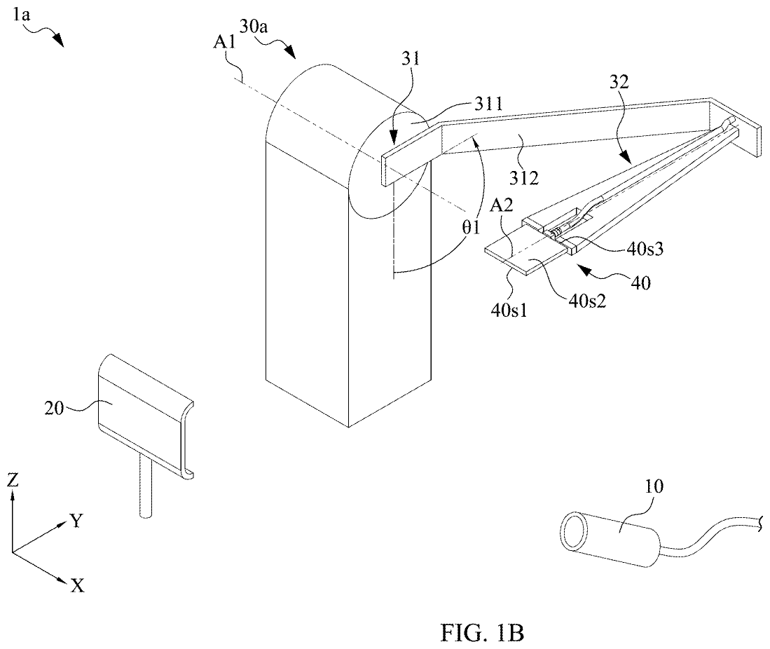

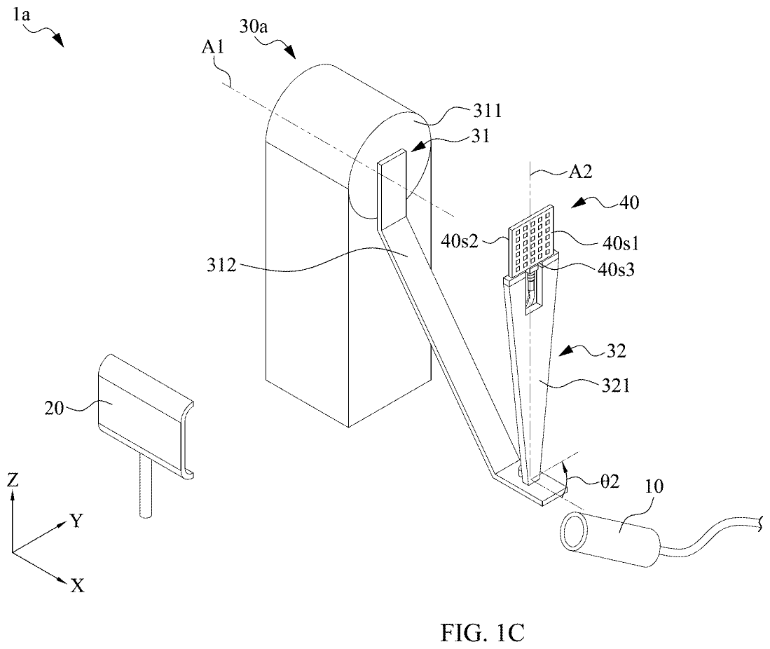

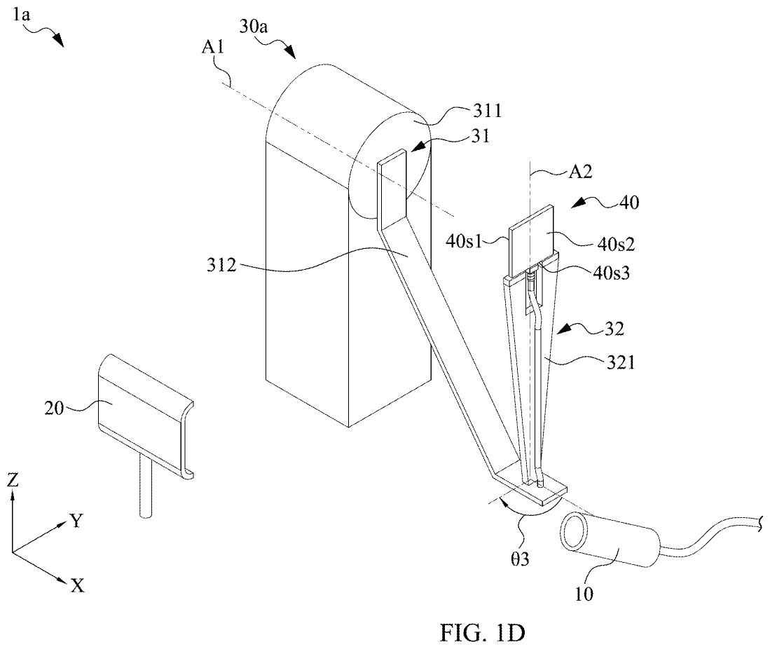

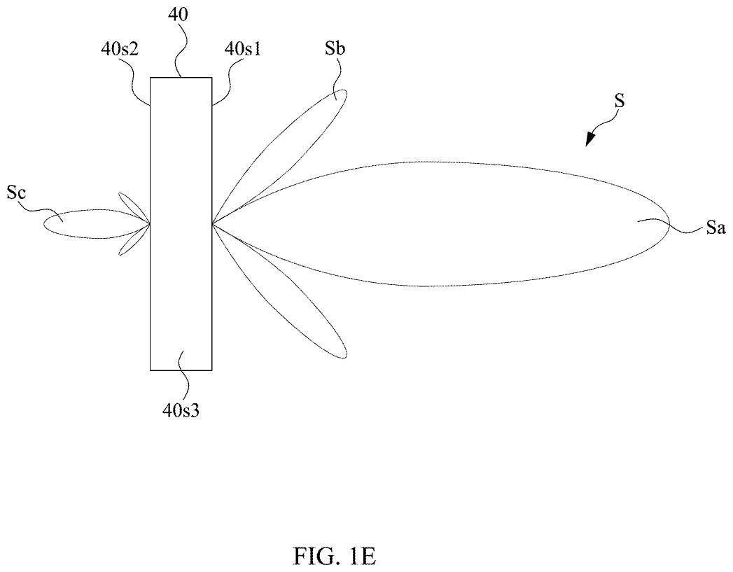

Arrangements disclosed herein relate to a measurement device that can reduce the blind angle of a radiation pattern of an antenna when performing measurements of the antenna. FIG. 1A is a perspective view of a measurement device 1a in accordance with some arrangements of the present disclosure. In some arrangements, the measurement device 1a may include at least an antenna 10, a reflector 20, and an AUT moving mechanism 30a. In some arrangements, the measurement device 1a may be configured to measure, calculate, and/or obtaining data/information of a radiation pattern of an antenna under test 40 (AUT), referred to as a first antenna. In some arrangements, the data and/or information captured by the measurement device 1a can be used to calculate a radiation pattern under a near-field range or under a compact range. In some examples, as described herein a processing unit including a processor and a memory can be operatively coupled to the measurement device 1a to obtain the data and/or information captured by the measurement device 1a and calculate the radiation pattern.

Examples of the antenna 10, which can be referred to as a second antenna, can include a feeding antenna, a test antenna, and so on. The antenna 10 may be configured to transmit and/or receive an electromagnetic wave, which may include a spherical wave, a plane wave, and the like. For example, the antenna 10 may be configured to transmit RF radiation to the AUT 40, and receive RF radiation sent from the AUT 40. In that regard, the antenna 10 may be driven by a suitable source to transmit the RF radiation. The antenna 10 may be configured to detect or receive RF radiation radiated from the AUT 40.

The reflector 20 may be configured to transform and/or convert an electromagnetic wave (e.g., a spherical wave) to a plane wave. The electromagnetic wave to be transformed or converted can include at least one of a main lobe, a side lobe, and a back lobe. The reflector 20 may be configured to facilitate in realizing a radio wave path that returns the RF radiation (e.g., a test signal and a measured signal) transmitted and/or received by the AUT 40 to and/or from the antenna 10. In some arrangements, the reflector 20 may be positioned such that the plane wave is received indirectly by the AUT 40 via the reflector 20. That is, the plane wave travels from the antenna 10 to the reflector 20, which redirects at least a portion or all of the plane wave toward the AUT 40. In some arrangements, the reflector 20 may be positioned such that the plane wave is received indirectly by the antenna 10 via the reflector 20. That is, the plane wave travels from the AUT 40 to the reflector 20, which reflects at least a portion or all of the plane wave toward the antenna 10.

In some arrangements, the AUT moving mechanism 30a may be configured to move the AUT 40. For example, the AUT moving mechanism 30a can include one or more suitable motors (e.g., DC motors, electrical motors, step motors, and so on) that can actuate movement of the AUT 40 in the manner described herein. In some arrangements, the AUT moving mechanism 30a may be configured to rotate the AUT 40. In some arrangements, the AUT moving mechanism 30a may be configured to rotate the AUT 40 (including the surfaces 40s1, 40s2, and 40s3) without changing the position (e.g., X coordinate, Y coordinate, and/or Z coordinate) of a geometric center of the AUT 40. In some arrangements, the AUT moving mechanism 30a may include a positioner 31 and a positioner 32. The positioners 31 and/or 32 may be configured to rotate the AUT 40 to perform a spherical scanning. As used herein a pose of the AUT 40 refers a position of the AUT 40 and an orientation of the AUT 40. The position of the AUT 40 refers to the location of a geometric center or another point of the AUT 40 defined by one or more points (e.g., one or more sets of x, y, z coordinates) in a suitable coordinate system (e.g., a Cartesian coordinate system as shown). The position of the AUT 40 can therefore be the same as the position of the geometric center or another point of the AUT 40. The orientation of the AUT 40 refers to the angle, alignment, and/or arrangement of the AUT 40. In different orientations, a surface (e.g., the surfaces 40s1, 40s2, and 40s3) of the AUT 40 may face different directions.

In some arrangements, the positioner 31 may be configured to move, rotate, and/or adjust the orientation of the AUT 40. In some arrangements, the positioner 31 may be configured to move (e.g., rotate) the AUT 40 around a rotation axis A1. In some arrangements, the rotation axis A1 may be aligned with, parallel to, or extend along the X-axis. The positioner 31 may include a rotation surface 311 and an extender 312 connected to the rotation surface 311. In some arrangements, the rotation surface 311 may be rotated around the rotation axis A1 by, for example, a motor (not shown). The extender 312 may extend from the rotation surface 311. In some arrangements, the extender 312 may have an end 312a (or a terminal) connected to the rotation surface 311 and an end 312b (or a terminal) connected to the positioner 32. In some examples, at least a portion of the end 312a is parallel to and/or directly contacting the rotation surface 311. In some examples, at least a portion of the end 312b is perpendicular to the rotational surface 311. In some arrangements, the extender 312 may be moved by a rotation of the rotation surface 311 by virtual of the extender 312 being connected to the rotation surface 311. In some arrangements, the extending direction of the extender 312 may be slanted with respect to a normal direction of the rotation surface 311. For example, at least a portion of a middle portion of the extender 312 extends in a direction oblique to the rotation surface 311. In some arrangements, the extender 312 of the positioner 31 may be configured to position the positioner 32 (e.g., an end 321a) to a position along the x and z axes, and at a predetermined distance relative to a point on the rotational surface 311. In some arrangements, when the AUT 40 is moved by at least the positioner 31, the geometric center or another point on the AUT 40 (e.g., a set of X coordinate, Y coordinate, and/or Z coordinate) may be substantially invariable or unchangeable.

In some arrangements, the positioner 32 may be configured to hold the AUT 40 relative to the positioner 31. In some arrangements, the positioner 32 may be configured to move, rotate, and/or adjust the orientation of the AUT 40 around a rotation axis A2 by, for example, a motor (not shown). In some arrangements, the positioner 32 may be configured to change an angle between a normal direction of a surface 40s1 of the AUT 40 and one or more of the Z-axis, X-axis, or Y-axis. The range of the angle, between the normal direction of a surface 40s1 of the AUT 40 and one or more of the Z-axis, X-axis, or Y-axis, may be equal to or greater than 0 and less than or equal to 360 degrees. In some arrangements, an angle between the rotation axis A2 and one or more of the Z-axis, X-axis, or Y-axis may depend on a rotation angle of the AUT 40 moved by the positioner 31. That is, although FIG. 1A illustrates that the rotation axis A2 is aligned with, parallel to, or extend along the Z-axis at a given pose of the AUT 40, positioner 31 and position 32, an angle between the rotation axis A2 and one or more of the Z-axis, X-axis, or Y-axis may change when the extender 312 is moved as described. In some arrangements, the rotation axis A2 may be substantially perpendicular to a normal direction of a surface 40s1 of the AUT 40 regardless of the pose of the AUT 40. In some arrangements, the positioner 32 may be configured to move the AUT 40 without moving a position (e.g., the geometric center or another suitable point) of the AUT 40. In some arrangements, a pose (including a position and an orientation) of the positioner 32 may be adjusted by operation or movement of the positioner 31.

The positioner 32 may include an extender 321. The extender 321 may be connected to the end 312b of the extender 312. In some arrangements, the extender 321 or a portion thereof may be rotated around the rotation axis A2. In some arrangements, the extender 321 may have an end 321a (or a terminal) connected to the extender 312 and an end 321b (or a terminal) configured to be connected or removably coupled to the AUT 40. In some arrangements, when the AUT 40 is moved by the extender 321, the position (e.g., a set of X coordinate, Y coordinate, and/or Z coordinate) of the AUT 40 may be invariable or unchangeable. In some arrangements, the extending direction of the extender 321 of the positioner 32 is substantially perpendicular to the normal direction of the surface 40s1 of the AUT 40. In some examples, as shown, the extender 321 has a shape that tapers from the end 321b to the end 321a along the extending direction.

The AUT 40 may be configured to receive RF radiation from the antenna 10. The AUT 40 may be configured to send RF radiation to the antenna 10. The AUT 40 may include a device capable of communicating via cellular standards (e.g., Long Term Evolution (LTE), LTE-A, Wideband Code Division Multiple Access (W-CDMA), Global System for Mobile (GSM), Code-Division Multiple Access (CDMA) reflector 2000, Evolution-Data Optimized (1×EV-DO), Time Division-Synchronous Code Division Multiple Access (TD-SCDMA), or the like), wireless Location Area Network (LAN) standards (IEEE 802.11b/g/a/n/ac/ad, or the like), Bluetooth standards, Global Navigation Satellite System (GNSS) (e.g., Global Positioning System (GPS), Galileo, Global Navigation Satellite System (GLONASS), BeiDou, or the like), Frequency Modulation (FM) standards, and digital broadcasting standards (e.g., Digital Video Broadcasting-Handheld (DVB-H), Integrated Services Digital Broadcasting-Terrestrial (ISDB-T), or the like). Further, the AUT 40 may be a wireless terminal that transmits and receives an RF signal in a millimeter wave band corresponding to IEEE 802.11ad, 5th Generation (5G) cellular, or the like.

The AUT 40 may have a surface 40s1, a surface 40s2, and a surface 40s3. In some arrangements, the surface 40s1 may be configured to radiate and/or send a main lobe of an electromagnetic wave, which has a greater field strength as compared to a side lobe. The surface 40s2 may be opposite to the surface 40s1. In some arrangements, the surface 40s2 may be configured to radiate and/or send a back lobe of an electromagnetic wave, which has a lower field strength as compared to the main lobe. The surface 40s3 may extend between the surfaces 40s1 and 40s2. At least a portion of the surface 40s3 may face the positioner 32. In some arrangements, the surface 40s3 may face the positioner 32 while at least one of the positioners 31 or 32 is being moved. In some arrangements, the AUT 40 may be moved and/or rotated by the AUT moving mechanism 30a so that a radiation pattern may be generated by at least one of the surface 40s1 or 40s2.

FIG. 1B is a perspective view of the measurement device 1a having a pose by operation (e.g., rotation) of the positioner 31. When the positioner 31 is rotated by θ1 (e.g., −90 degrees) around the rotation axis A1 relative to the orientation of the positioner 31 as shown in FIG. 1A. The rotation axis A2 may be aligned with, parallel to, or along the Y-axis as a result. The normal direction of the surface 40s1 of the AUT 40 may be substantially parallel to the Z-axis. In comparison with FIG. 1A, an angle between the normal direction of the surface 40s1 of the AUT 40 and the Z-axis (or X-axis or Y-axis) is changed. In some arrangements, an angle between the normal direction of the surface 40s1 of the AUT 40 and the Z-axis (or X-axis or Y-axis) may depend on a rotation angle (e.g., θ1) of the AUT 40 moved by the positioner 31. In some arrangements, the position (e.g., the geometric center or another point) of the AUT 40 is not changed by operation of the positioner 31, although the orientation of the AUT 40 has changed. In some arrangements, the rotation axis A1 may be substantially perpendicular to the rotation axis A2.

FIG. 1C is a perspective view of the measurement device 1a having a pose by operation (e.g., rotation) of positioner 32. When the positioner 32 is rotated by θ2 (e.g., −90 degrees) relative to the orientation of the positioner 32 as shown in FIG. 1A around the rotation axis A2 relative to the orientation of the positioner 32 as shown in FIG. 1A. The surface 40s2 of the AUT 40 may face the positioner 31.

FIG. 1D is a perspective view of the measurement device 1a having a pose by operation (e.g., rotation) of positioner 32. When the positioner 32 is rotated by θ3 (e.g., 90 degrees) around the rotation axis A2 relative to the orientation of the positioner 32 as shown in FIG. 1A, the surface 40s1 of the AUT 40 may face the positioner 31.

As shown in FIG. 1C and FIG. 1D, the positioner 32 may be configured to enable the surfaces 40s1 and 40s2 to face the positioner 31. The positioner 32 may be configured to move the AUT 40 to allow the surfaces 40s1 and 40s2 to face the reflector 20 by a rotation of the AUT 40 with operation of the positioner 32.

FIG. 1E is a schematic view of RF radiation S radiated from the AUT 40. As shown in FIG. 1E, the surface 40s1 of the AUT may radiate the main lobe Sa and the side lobe Sb of RF radiation S (or electromagnetic wave). The surface 40s2 may radiate the back lobe Sc of RF radiation S.

In some arrangements, the AUT 40 may be moved in an angular direction around the rotation axis A1, for example, within a range of 360 degrees by operation of the positioner 31. In some arrangements, the AUT 40 may be moved in an angular direction around the rotation axis A2, for example, within a range of 360 degrees by operation of the positioner 32. In some arrangements, the AUT 40 can be rotation along both the axes A1 and A2. As a result, a radiation pattern, which has a substantially spherical profile, can be generated. Further, the main lobe Sa, side lobe Sb, and/or back lobe Sc may be measured without an obstruction as the AUT 40 can be lobed by the positioners 31 and 32. For example, when the surface 40s1 of the AUT faces the reflector 20, wireless signals carried in the main lobe Sa and the side lobe Sb of RF radiation S may be transmitted toward the reflector 20 without an obstruction. When the surface 40s2 of the AUT 40 faces the reflector 20, the back lobe Sc of RF radiation S may be transmitted toward the reflector 20 without an obstruction. Therefore, the positioners 31 and/or 32 may enable the main lobe Sa, side lobe Sb, and/or back lobe Sc to be detected via the antenna 40 with improved accuracy. The main lobe Sa, side lobe Sb, and/or back lobe Sc may face the positioner 31 or face away from the positioner 31 by operation of the positioner 32.

In some arrangements, the position (e.g., the geometric center or another point) of the AUT 40 is not substantially changed by operation (e.g., rotation) of the positioners 31 and/or 32. In some arrangements, the position (e.g., the geometric center or another point) of the AUT 40 for a first pose may be changed by a distance with respect to the position of the AUT 40 for a second pose. The first pose and the second pose are different poses achieved by moving at least one of the positioner 31 or positioner 32. Any distance between any given first pose and any given second pose is less than a size (e.g., length, height, width, radius, and so on) of the AUT 40.

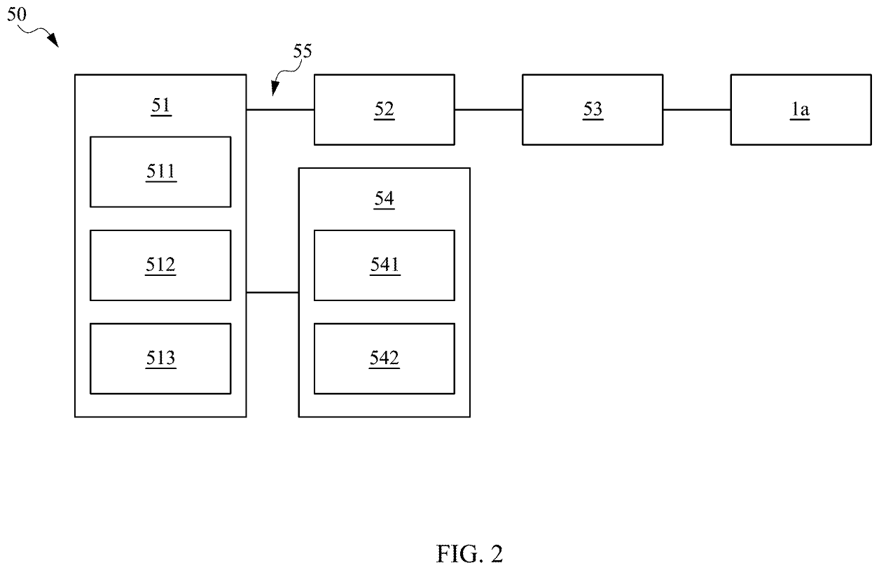

FIG. 2 is a schematic view of a system 50 for determining a radiation pattern of the AUT 40 in accordance with some arrangements of the present disclosure. In some arrangements, the system 50 may include a calculating unit 51, a signal control unit 52, a signal processing unit 53, a AUT moving mechanism 54, and a network 55. The system 50 may be operatively coupled to the measurement device 1a and may be receive signals, data, or information from the measurement device 1a.

The calculating unit 51 may be configured to calculate a three-dimensional radiation pattern of the electromagnetic wave from the AUT (e.g., 40). The calculating unit 51 may include, for example, a computer device. The computer device may include a Central Processing Unit (CPU) that performs predetermined information processing to realize the function of the measuring device 1a, and performs comprehensive control on the signal control unit 52. In some arrangements, the calculating unit 51 may calculate a radiation pattern by collecting RF signals by rotating the positioner 31 within a range of 360 degrees. In some arrangements, the calculating unit 51 may calculate a radiation pattern by collecting RF signals by rotating the positioner 32 within a range of 360 degrees. In some arrangements, the calculating unit 51 may include a signal transmission and/or reception unit 511, an AUT moving mechanism control unit 512, and a signal analysis control unit 513.

The signal transmission and/or reception unit 511 may be configured to transmit a signal transmission command to the signal control unit 52. The signal transmission and/or reception unit 511 may be configured to transmit a test signal from the signal control unit 52 via the antenna 10, as shown in FIG. 1A, of the measurement device 1a. The signal transmission and/or reception unit 511 may be configured to control transmission of a signal reception command and receive the measured signal via the antenna 10 of the measurement device 1a.

The AUT moving mechanism control unit 512 may be configured to drive and control the AUT 40. The AUT moving mechanism control unit 512 may store, for example, rotation angles of each of the positioners 31 and 32 (shown in FIGS. 1A-1D as well as other rotational angles). The AUT moving mechanism control unit 512 may be configured to store data of the network 55 associated with the rotation angles of each of the positioners 31 and 32. The AUT moving mechanism control unit 512 may be configured to control data associated with a measurement time at each rotation angles of each of the positioners 31 and 32.

The signal analysis control unit 513 may be configured to capture RF radiation signal, which is received (or detected) by the antenna 10 of the measurement device 1a via the signal control unit 22. The signal analysis control unit 513 may be configured to perform an analysis process (measurement process) on the RF radiation signal as a signal of a measurement item, such as total radiated power (TRP), equivalent isotropic radiated power (EIRP), or other radiation patterns.

The signal control unit 52 may be communicably connected to the calculating unit 51 via the network 55. The signal control unit 52 may be configured to generate a test signal to the antenna 10 (shown in FIG. 1A) of the measurement device 1a. The signal control unit 52 may be configured to generate a test signal to the signal processing unit 53, and restore a measured signal, received (or detected) by the antenna 10, from the signal processing unit 53.

The AUT moving mechanism 54 may be communicably connected to the calculating unit 51 via the network 55. The AUT moving mechanism 54 may be configured to actuate a rotation angle of the positioners 31 and/or 32. The AUT moving mechanism 54 may include a motor 541 and a motor 542. In some arrangements, the motor 541 may be configured to rotate the positioner 31. In some arrangements, the motor 541 may be configured to actuate a rotation angle of the positioner 31. The unit movement angle of the rotation angle of the positioner 31 can be actuated by the motor 541. The unit movement angle may define a measurement angle of the AUT 40. When one of measurements of a measured signal is completed, the motor 541 may drive the positioner 31 to move the AUT 40 to a next measurement angle by the unit movement angle. The unit movement angle may be a value, such as 5 degrees, 10 degrees, 15 degrees, 20 degrees, 30 degrees, 90 degrees, or other suitable values.

In some arrangements, the motor 542 may be configured to rotate the positioner 32. In some arrangements, the motor 542 may be configured to actuate a rotation angle of the positioner 32. A unit movement angle of the rotation angle of the positioner 32 may be actuated by the motor 542. When one of measurements of a measured signal is completed, the motor 542 may drive the positioner 32 to move the AUT 40 to a next measurement angle by the unit movement angle. The unit movement angle may be a value, such as 5 degrees, 10 degrees, 15 degrees, 20 degrees, 30 degrees, 90 degrees, or other suitable values. In some examples, the unit movement angle for the positioner 31 is different from the unit movement angle for the positioner 32. In some examples, the unit movement angle for the positioner 31 is the same as the unit movement angle for the positioner 32.

In some arrangements, each time the AUT 40 is moved by the positioner 31 by a unit movement angle (e.g., 15 degrees), the AUT 40 may be moved by the positioner 32 by a plurality (e.g., N) of unit movement angles (e.g., 30 degrees) to complete a part of measurements of generating a radiation pattern by taking N measurements for each of N unit movement angles of the positioner 32. For example, when the AUT 40 is rotated around the rotation axis A1 by 15 degrees, the AUT 40 is rotated around the rotation axis A2 by 30 degrees. After a measured signal is received by the calculating unit 51, the AUT 40 is rotated around the rotation axis A2 by 30 degrees again to reach next measurement angle. After the AUT 40 is rotated around the rotation axis A2 by 360 degrees, the AUT 40 is rotated around the rotation axis A1 by 15 degrees again to continue next measurements. Thus, for each unit movement angle for one of the positioners 31 or 32, one or a plurality of measurements (e.g., N) can be generated by moving the other one of the positioners 31 or 32 one or a plurality (e.g., N) of times.

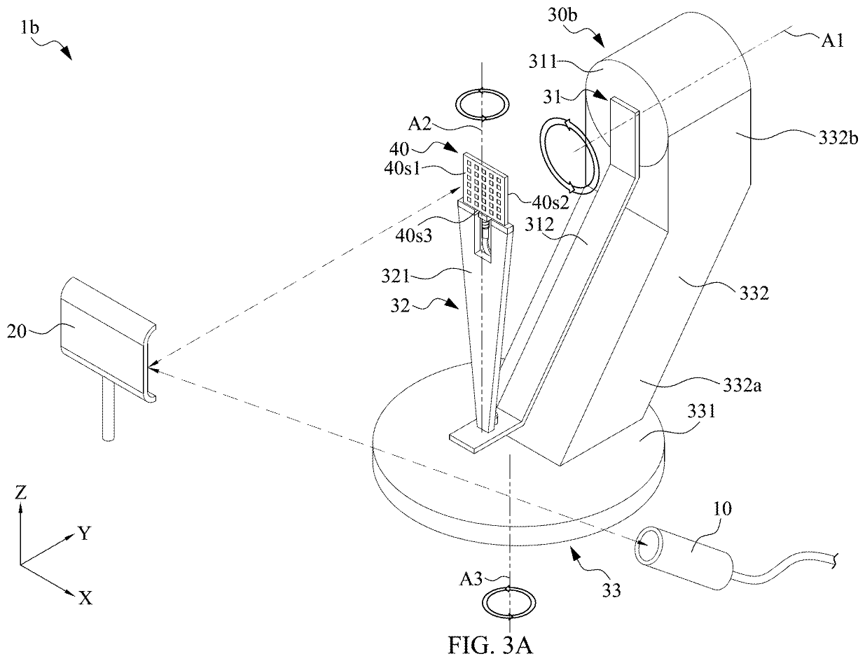

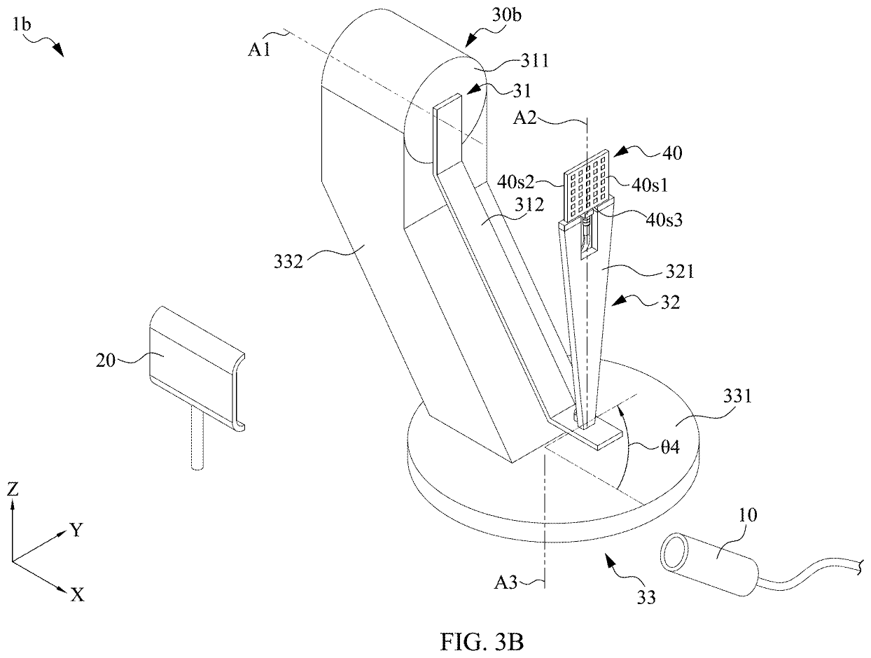

FIG. 3A and FIG. 3B are perspective views of a measurement device 1b in accordance with some arrangements of the present disclosure. The measurement device 1b may be similar to the measurement device 1a as shown in FIG. 1A, except that the measurement device 1b may include a AUT moving mechanism 30b replacing the AUT moving mechanism 30a.

In some arrangements, the AUT moving mechanism 30b may further include a positioner 33. In some arrangements, the positioner 31 may be connected between the positioners 32 and 33. In some arrangements, the positioner 33 may be configured to move the AUT 40 around a rotation axis A3. In some arrangements, the rotation axis A3 may be aligned with, parallel to, or extend along the Z-axis. In some arrangements, the rotation axis A3 may be substantially perpendicular to the rotation axis A1. The positioner 33 may include a rotation surface 331 and an extender 332 connected to the rotation surface 331. In some arrangements, the rotation surface 331 may be rotated around the rotation axis A3 by, for example, a motor (not shown). The extender 332 may extend from the rotation surface 331. In some arrangements, the extender 332 may have an end 332a connected to the rotation surface 331 and an end 332b connected to the positioner 31. In some arrangements, the extender 332 may be moved by a rotation of the rotation surface 331. In some arrangements, the extending direction of the extender 332 may be slanted with respect to a normal direction of the rotation surface 331. For example, at least a portion of a middle portion of the extender 332 extends in a direction oblique to the rotation surface 311.

FIG. 3B is a perspective view of the measurement device 1b having a pose by operation (e.g., rotation) of positioner 33. When the positioner 33 is rotated by θ4 (e.g., −90 degrees) around the rotation axis A3 relative to the orientation of the positioner 33 as shown in FIG. 3A, the normal direction of the surface 40s1 of the AUT 40 may also be rotated by θ4. In comparison with FIG. 3A, an angle between the normal direction of the surface 40s1 of the AUT 40 and the Y-axis or X-axis is changed. In some arrangements, an angle between the normal direction of the surface 40s1 of the AUT 40 and the Y-axis or X-axis may depend on a rotation angle (e.g., θ4) of the AUT 40 moved by the positioner 33. The positioner 33 may facilitate the measurement of the radiation pattern with less time. In some arrangements, either the positioners 31, 32, 33, and a combination thereof may be considered as one positioner. In some arrangements, the positioners 31 and 32 may be considered as the first positioner, and the positioner 32 may be considered as the second positioner which is included in the first positioner. In some arrangements, the positioner 31 may be considered as the first positioner, the positioner 32 may be considered as the second positioner, and the positioner 33 may be considered as the third positioner.

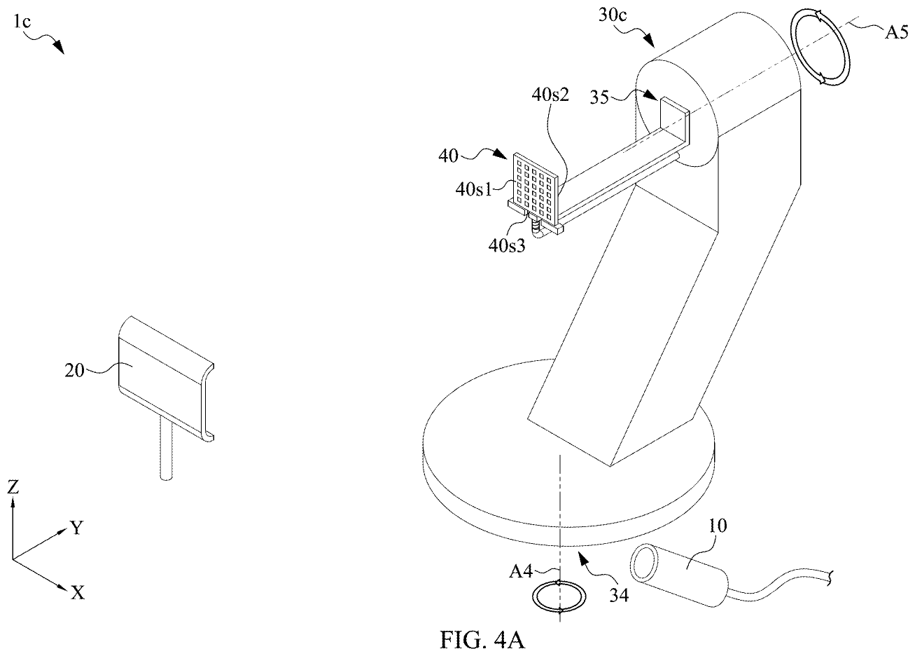

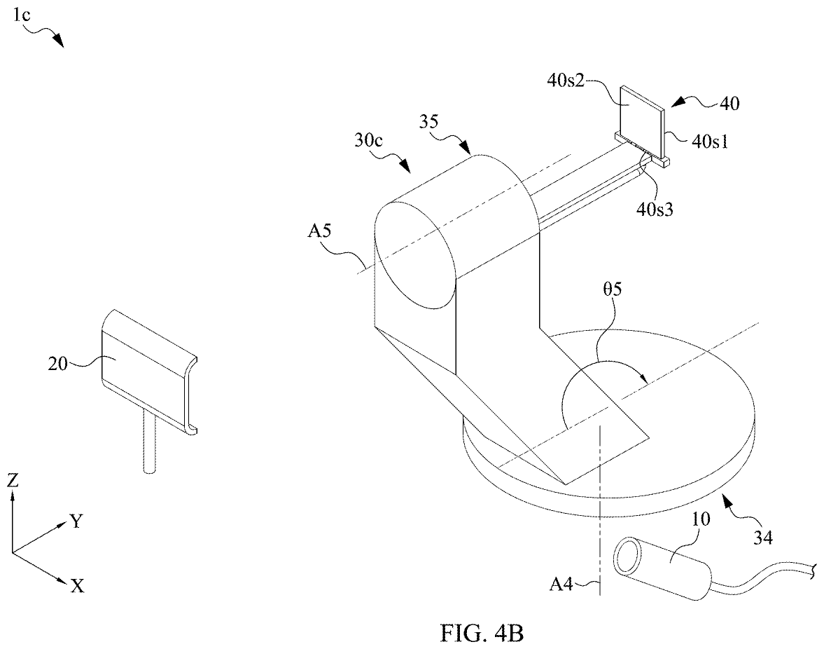

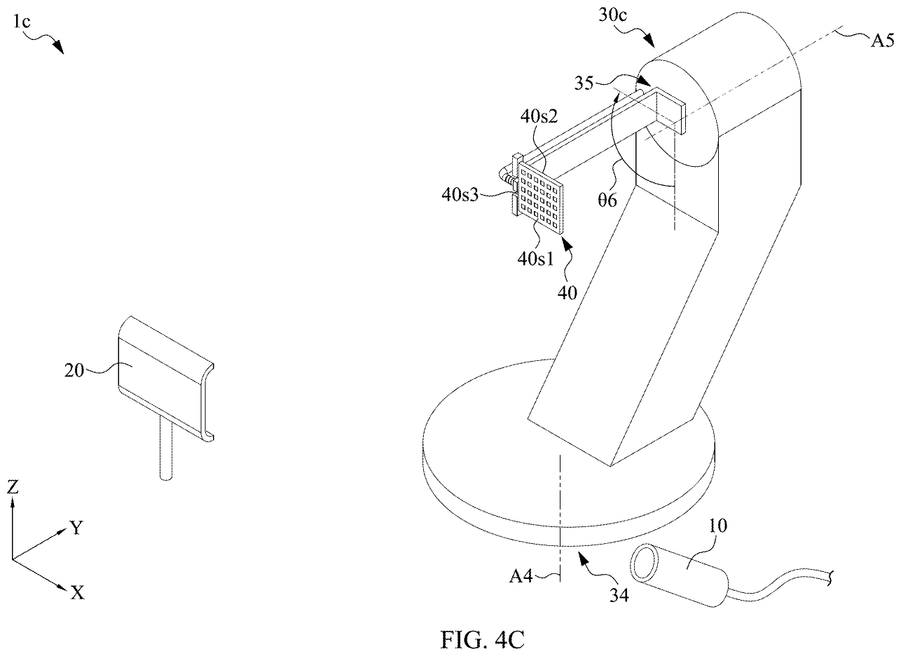

FIG. 4A is a perspective view of a measurement device 1c. The measurement device 1c may include an AUT moving mechanism 30c. The AUT moving mechanism 30c may include a positioner 34 and a positioner 35.

The positioner 34 may be configured to move the AUT 40 around a rotation axis A4. The rotation axis A4 may be aligned with, parallel to, or extend along the Z-axis. The positioner 35 may hold the AUT 40. The positioner 35 may be connected to the positioner 34. The positioner 35 may be configured to move the AUT 40 around a rotation axis A5. The rotation axis A5 may be aligned with, parallel to, or extend along the Y-axis. The surface 40s1 of the AUT 40 faces away from the positioner 35. The surface 40s2 of the AUT 40 faces the positioner 35.

FIG. 4B is a perspective view of the measurement device 1c having a pose by rotation of the positioner 34. When the positioner 34 is rotated by θ5 (e.g., 180 degrees) around the rotation axis A4 relative to the pose (e.g., the position and the orientation) of the positioner 34 as shown in FIG. 4A, the pose (e.g., the position and the orientation) of the AUT 40 may also be changed. However, the surface 40s2 of the AUT 40 remains facing the positioner 35, which causes a relatively large blind angle of the radiation patterns.

FIG. 4C is a perspective view of the measurement device 1c having a pose by a rotation of the positioner 35. When the positioner 35 is rotated by θ6 (e.g., 90 degrees) around the rotation axis A5 relative to the orientation of the positioner 35 as shown in FIG. 4A, the normal direction of the surface 40s1 of the AUT 40 is unchanged. The position of the AUT 40 is not be changed.

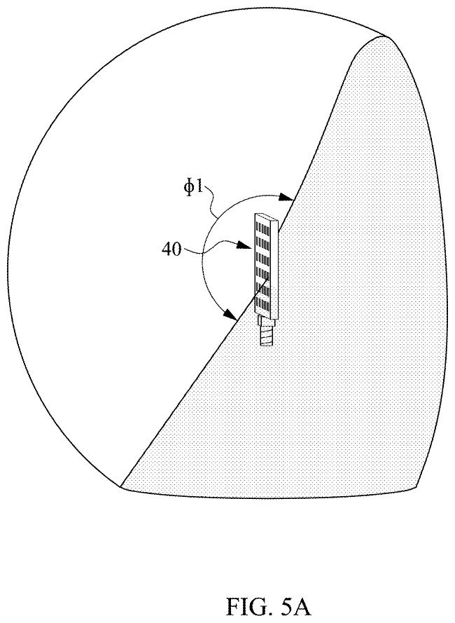

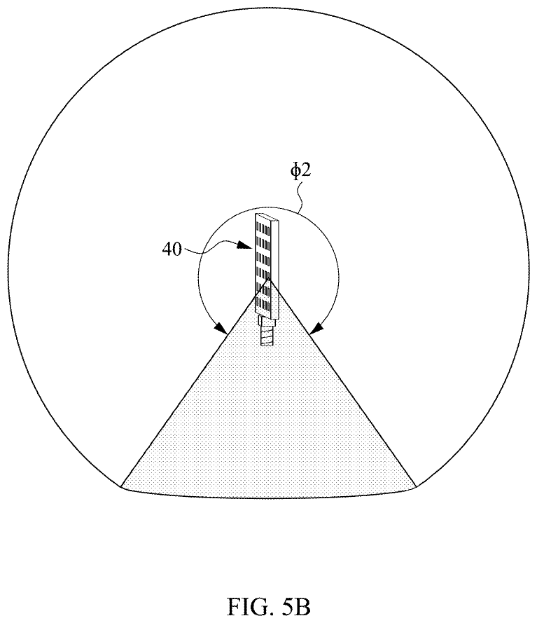

FIG. 5A is a schematic view of a radiation pattern measured by a measurement device, such as the measurement device 1c. The shaded area of the radiation pattern may correspond to an area of RF radiation of the AUT 40 that cannot be detected, which may correspond to the blind angle of the radiation pattern. The white area of the radiation pattern may correspond to an area of RF radiation of the AUT 40 that can be detected, and the white area may be configured to determine the solid angle of the radiation pattern. The solid angle of a measurement of a radiation pattern can be determined by the formula: Ω=A/r², wherein Ω indicates a solid angle which a measurement device can measure with a signal strength greater than a predetermined value, A indicates a surface area of the radiation pattern which a measurement device can measure with a signal strength greater than a predetermined value, and r indicates a radius of the radiation pattern. The radiation pattern as shown in FIG. 5A has a solid angle Φ1 of about 468 degree. The coverage percentage of the radiation pattern can be determined by the formula: Ω/4π. The radiation pattern as shown in FIG. 5A has a coverage percentage of about 65%. The radiation pattern as shown in FIG. 5A may have a blind angle of 70 degrees along the altitude axis, which may correspond to the rotation axis A5 of FIG. 4A. The radiation pattern as shown in FIG. 5A may have a blind angle of 120 degrees along the azimuth axis, which may correspond to the rotation axis A4 of FIG. 4A.

FIG. 5B is a schematic view of a radiation pattern measured by a measurement device (e.g., 1a and/or 1b) in accordance with some arrangements of the present disclosure. The radiation pattern as shown in FIG. 5B can be achieved using the measurement device 1a and/or 1b shown in FIG. 1A and/or FIG. 3A and has a solid angle Φ2 of about 655 degrees. The radiation pattern as shown in FIG. 5B has a coverage percentage of about 91%. The radiation pattern as shown in FIG. 5B may have a blind angle of 70 degrees along the altitude axis, which may correspond to the rotation axis A3 of FIG. 3A. The radiation pattern as shown in FIG. 5B may have a blind angle of 0 along the azimuth axis, which may correspond to the rotation axis A1 of FIG. 3A. In this arrangement, the radiation pattern measured by the measurement devices 1a and/or 1b may have a blind angle less than 30 degrees, such as 30 degrees, 20 degrees, 10 degrees, 5 degrees, 3 degrees, or 0, along the azimuth axis. In this arrangement, the radiation pattern measured by the measurement devices 1a and/or 1b may have a coverage percentage greater than 70 degrees, such as 70 degrees, 80 degrees, 85 degrees, 90 degrees, 91 degrees, or more.

As shown in FIG. 4A to FIG. 4C, the surface 40s2 of the AUT 40 always faces the positioner 35 so that the RF radiation at a location adjacent to the surface 40s2 of the AUT 40 cannot be measured accurately because RF radiation from the surface 40s2 is obstructed by the positioner 35. As a result, the radiation pattern measured by the measurement device 1c in FIG. 4A to FIG. 4C has a relative large blind angle and a small coverage percentage. In the arrangements of this disclosure, both surfaces 40s1 and 40s2 of the AUT 40 may face the positioner 31 by operation (e.g., rotation) of the positioner 32. As a result, the radiation pattern measured by the measurement devices 1a and/or 1b may have a relative great coverage percentage.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only and that practical implementations of the structures described herein can be spatially arranged in any orientation or manner, provided that the merits of arrangements of this disclosure are not deviated from by such an arrangement.

As used herein, the term “vertical” is used to refer to upward and downward directions, whereas the term “horizontal” refers to directions transverse to the vertical directions.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3º, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no exceeding 5 μm, no exceeding 2 μm, no exceeding 1 μm, or no exceeding 0.5 μm. A surface can be deemed to be substantially flat if a displacement between the highest point and the lowest point of the surface is no exceeding 5 μm, no exceeding 2 μm, no exceeding 1 μm, or no exceeding 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity exceeding approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific arrangements thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit, and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A measurement device for performing measurements of a first antenna, comprising:
at least one positioner configured to move the first antenna for measuring a main lobe and a back lobe of an electromagnetic wave radiated from the first antenna.

2. The measurement device of claim 1, wherein the at least one positioner is configured to adjust an orientation of the first antenna.

3. The measurement device of claim 2, wherein the at least one positioner is configured to move the first antenna for measuring a side lobe of the electromagnetic wave radiated from the first antenna.

4. The measurement device of claim 2, wherein the at least one positioner is configured to rotate the first antenna for performing a spherical scanning of the first antenna to generate a radiation pattern of the first antenna.

5. The measurement device of claim 1, wherein the back lobe of the electromagnetic wave is measured under a near-field range or under a compact range.

6. The measurement device of claim 5, further comprising:
a second antenna configured to receive the main lobe and the back lobe of the electromagnetic wave radiated from the first antenna.

7. The measurement device of claim 6, further comprising:
a reflector configured to transform the electromagnetic wave to a plane wave, wherein the second antenna is configured to receive the electromagnetic wave indirectly via the reflector.

8. The measurement device of claim 7, wherein the at least one positioner is further configured to move both a first surface and a second surface opposite to the first surface of the first antenna to face the reflector.

9. The measurement device of claim 1, further comprising:
a calculating unit configured to calculate a radiation pattern based on the electromagnetic wave radiated from the first antenna.

10. The measurement device of claim 1, wherein the at least one positioner comprises a first positioner and a second positioner, and the at least one positioner adjusts an orientation of the first antenna using the first positioner and the second positioner.

11. The measurement device of claim 10, wherein the first positioner is configured to move the first antenna around a first rotation axis, the second positioner is configured to move the first antenna around a second rotation axis substantially perpendicular to the first rotation axis.

12. A measurement device for performing measurements of an antenna under test (AUT), comprising:
a first positioner configured to move the AUT around a first rotation axis along a first axis; and
a second positioner configured to hold the AUT and configured to adjust an angle between a normal direction of a first surface of the AUT and the first axis.

13. The measurement device of claim 12, wherein the second positioner is configured to move the AUT in an orientation in which a back lobe of an electromagnetic wave radiated from the AUT to face away from the first positioner.

14. The measurement device of claim 12, wherein the first positioner is configured to rotate the second positioner around the first rotation axis.

15. The measurement device of claim 14, wherein the first positioner comprises an extender configured to determine a position of the second positioner.

16. The measurement device of claim 12, wherein a range of the angle is equal to or greater than 0 and less than or equal to 360 degrees.

17. A method of measuring a radiation pattern of a first antenna, comprising:
providing a second antenna configured to detect an electromagnetic wave radiated from the first antenna;
moving an orientation of the first antenna to detect a back lobe of the electromagnetic wave radiated from the first antenna via the second antenna; and
calculating a radiation pattern based on the electromagnetic wave detected by the second antenna.

18. The method of claim 17, wherein the back lobe of the electromagnetic wave is transformed to a plane wave.

19. The method of claim 17, further comprising:
providing a first positioner configured to rotate the first antenna around a first rotation axis.

20. The method of claim 19, further comprising:
providing a second positioner configured to rotate the first antenna around a second rotation axis, wherein the second positioner is connected to the first positioner.
